(19) United States
(12) Patent Application Publication
(10) Pub. No.: US 2007/0227588 A1
(43) Pub. Date: Oct. 4, 2007

(54) ENHANCED TUNNEL JUNCTION FOR IMPROVED PERFORMANCE IN CASCADED SOLAR CELLS

(75) Inventors: Arthur C. Gossard, Santa Barbara, CA (US); Joshua M. O. Zide, Goleta, CA (US); Jeramy D. Zimmerman, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/675,269

(22) Filed: Feb. 15, 2007

Related U.S. Application Data
(60) Provisional application No. 60/773,434, filed on Feb. 15, 2006.

(51) Int. Cl. H01L 31/00

(52) U.S. Cl. 136/255

(57) ABSTRACT

A method and device that incorporates metallic nanoparticles at the p⁺-n⁺ tunnel junction in a cascaded photovoltaic solar cell. The use of the nanoparticles enhances the tunneling current density through the tunnel junction. As such, the efficiency of the solar cell is increased. A method in accordance with the present invention comprises making a first solar cell having a first bandgap, making a tunnel junction coupled to the first solar cell, and making a second solar cell having a second bandgap, coupled to the tunnel junction opposite the first solar cell, wherein the tunnel junction comprises nanoparticles. Such a method further optionally includes the nanoparticles being a metal or a semi metal, specifically a semi-metal of erbium arsenide, the nanoparticles being deposited in an island structure within the tunnel junction, and the first solar cell being deposited on a flexible substrate. A device in accordance with the present invention comprises a tunnel junction, wherein the tunnel junction comprises nanoparticles between the n+ layer and the p+ layer of the tunnel junction. Such a device further optionally includes the device being a cascaded solar cell, the nanoparticles are a metal or semi-metal, specifically a semi-metal of erbium arsenide, and the device is fabricated on a flexible substrate.

### CROSS-REFERENCE TO RELATED APPLICATIONS

This application claims the benefit under 35 U.S.C. § 119(e) of co-pending and commonly-assigned U.S. provisional patent application Ser. No. 60/773,434, filed Feb. 15, 2006, entitled “ENHANCED TUNNEL JUNCTION FOR IMPROVED PERFORMANCE IN CASCADED SOLAR CELLS,” by Arthur C. Gossard et al., which application is incorporated by reference herein.

### STATEMENT REGARDING FEDERALLY SPONSORED RESEARCH AND DEVELOPMENT

This invention was made with Government support under Grant No. 442530-23110, awarded by the Office of Naval Research. The Government has certain rights in this invention.

### BACKGROUND OF THE INVENTION

1. Field of the Invention

The present invention is generally related to solar cells, and, in particular, to a method, apparatus, and article of manufacture for an enhanced tunnel junction in cascaded solar cells.

2. Description of the Related Art

(Note: This application references a number of different publications and patents as indicated throughout the specification by one or more reference numbers within brackets, e.g., [x]. A list of these different publications and patents ordered according to these reference numbers can be found below in the section entitled “References.” Each of these publications and patents is incorporated by reference herein.)

Solar energy created through the photovoltaic effect is the main source of power for most spacecraft, and is becoming an attractive alternative for power generation for home, commercial, and industrial use. The amount of power generated by an array of solar cells is limited by the amount of solar cell area, and in the case of spacecraft use, the weight of the solar array. To be able to increase power delivery capability, the power per unit area for the solar cell array must be increased. Increasing the efficiency of the solar cell is of primary importance for solar cell manufacturers. The dominant solar cell technology for this application is a combination of sub cells comprising Gallium Indium Phosphide (GaInP), Gallium Arsenide (GaAs), and Germanium (Ge), which is typically called a cascaded solar cell.

Several approaches have been used to try to make solar cells more efficient or less costly. One approach is to use a multiple quantum-well (MQW) approach, which makes the efficiency of the overall device go up but also makes the cells much more expensive because of the tolerances required to make an MQW structure. Other approaches use additional subcell structures, or try to mismatch the subcell materials, each of which adds to the cost as well as the weight of the cell, limiting the usefulness of such approaches.

It can be seen, then, that there is a need in the art for more efficient solar cells.

### SUMMARY OF THE INVENTION

The present invention discloses a method that incorporates metallic nanoparticles at the p⁺-n⁺ tunnel junction in a cascaded photovoltaic solar cell. The use of the nanoparticles enhances the tunneling current density through the tunnel junction. As such, the efficiency of the solar cell is increased.

The nanoparticles provide an additional quantum state within the tunnel barrier, and, therefore, effectively reduce the tunneling distance. Because the probability of tunneling decreases exponentially with increasing barrier thickness, the effective decrease in barrier thickness exponentially increases the tunneling current. Passing the higher current without a large voltage drop improves the efficiency of the solar cell, so reducing the voltage drop in the tunnel junction improves the efficiency of the entire photovoltaic solar cell.

A method in accordance with the present invention comprises making a first solar cell having a first bandgap, making a tunnel junction coupled to the first solar cell, and making a second solar cell having a second bandgap, coupled to the tunnel junction opposite the first solar cell, wherein the tunnel junction comprises nanoparticles.

Such a method further optionally includes the nanoparticles being a metal or a semi metal, specifically a semi-metal of erbium arsenide, or a narrow bandgap semiconductor material, the nanoparticles being deposited in an island structure within the tunnel junction, and the first solar cell being deposited on a flexible substrate.

A device in accordance with the present invention comprises a tunnel junction, wherein the tunnel junction comprises nanoparticles between the n+ layer and the p+ layer of the tunnel junction.

Such a device further optionally includes the device being a cascaded solar cell, the nanoparticles are a metal or a semi-metal, specifically a semi-metal of erbium arsenide, or a narrow bandgap semiconductor material, the device being fabricated on a flexible substrate, the device having a plurality of active regions interconnected with a plurality of tunnel junctions, and current is passed through the plurality of tunnel junctions under reverse bias in order to generate electron-hole pairs in each active region in the plurality of active regions, and at least one tunnel junction of the plurality of tunnel junctions is an enhanced tunnel junction with reduced resistance.

A cascaded solar cell in accordance with the present invention comprises a first cell having a first bandgap, a tunnel junction, coupled to the first cell, the tunnel junction further comprising a plurality of nanoparticles, and a second cell having a second bandgap, the second cell being coupled to the tunnel junction, wherein the second bandgap is wider than the first bandgap.

Such a cascaded solar cell further optionally includes the plurality of nanoparticles being located between an n+ layer and a p+ layer of the tunnel junction, the nanoparticles being a metal or a semi-metal, the nanoparticles being erbium arsenide, and the nanoparticles being a narrow bandgap semiconductor material.

Still other aspects, features, and advantages of the present invention are inherent in the systems and methods claimed and disclosed or will be apparent from the following detailed description and attached drawings. The detailed description and attached drawings merely illustrate particular embodiments and implementations of the present invention, however, the present invention is also capable of other and different embodiments, and its several details can be modified in various respects, all without departing from the spirit and scope of the present invention. Accordingly, the drawings and description are to be regarded as illustrative in nature, and not as a restriction on the present invention.

### BRIEF DESCRIPTION OF THE DRAWINGS

Referring now to the drawings in which like reference numbers represent corresponding parts throughout:

FIG. 1 illustrates a cross section of a two-junction solar cell in accordance with the present invention;

FIGS. 2A and 2B illustrate Fermi-levels for the related art and for a solar cell in accordance with the present invention; and

FIG. 3 is a flowchart illustrating a method for employing the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Typically, a cascaded photovoltaic solar cell is used to achieve efficiencies higher than are possible with a single bandgap photovoltaic cell. The present invention comprises a method of improving the efficiency of these devices by adding nanoparticles to the interface of a tunnel junction to increases the efficiency of a cascaded photovoltaic solar cell.

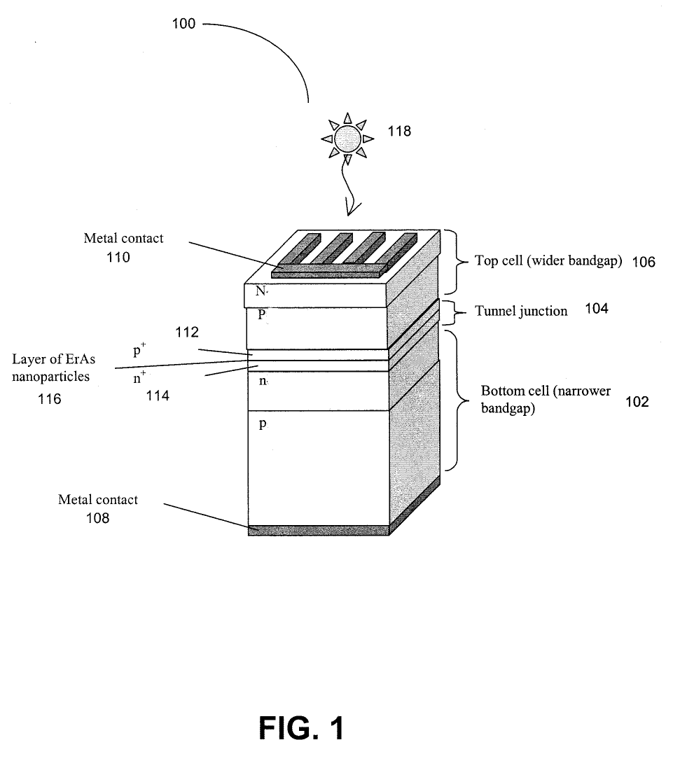

Generally, a cascaded photovoltaic consists of two or more semiconductor p-n diodes interconnected with an n⁺p⁺ diode, which is also known as a tunnel junction. (FIG. 1) The tunnel junction is usually (but not always) grown in situ during the growth of the photovoltaic material. The state-of-the-art tunnel junction consists of heavily doped semiconductors in intimate contact, which creates a narrow depletion region allowing tunneling. This tunneling results in so-called electron-hole conversion and allows the voltages generated in the p-n diodes to be added in series.

Illustration of the Invention

FIG. 1 illustrates a cross section of a two-junction solar cell in accordance with the present invention.

Cascaded solar cell 100 is shown, comprising bottom cell 102 having a first bandgap, tunnel junction 104, and top cell 106 having a second bandgap. Metal contacts 108 and 110 allow for electrical connection to cascaded solar cell 100. Within tunnel junction 104 are p+ layer 112, n+ layer 114, and a layer of nanoparticles 116 between the p+ layer 112 and n+ layer 114. When light 118 strikes the surface of cascaded solar cell 100, top cell 104 generates current, and light 118 passes through top cell 106 to bottom cell 102, which also generates current. However, top cell 106 and bottom cell 102 are in series, so for the current to reach from bottom cell 102 through to top cell 106, it must pass through tunnel junction 104. This is where localized heating and voltage drops occur in the related art, and the present invention minimizes these effects.

Although shown as Gallium Arsenide (GaAs), other materials that are used for solar cells, such as germanium, indium phosphide, nitride-based materials, and oxide-based materials, can also be used within the present invention. Further, although Erbium Arsenide (ErAs) is shown as the nanoparticle material, other materials, such as other metals or semi-metals, or a narrow bandgap semiconductor material, can be used without departing from the scope of the present invention.

The nanoparticle layer 116 provides additional quantum states between the p+ layer 112 and the n+ layer 114 which makes it easier for the electrons to tunnel across the tunnel junction 104. Although the physical distance of the tunnel junction 104 is the same, the nanoparticles 116 make it easier for the electrons to pass through; rather than a large tunneling barrier, the nanoparticles 116 provide a series of smaller barriers, somewhat akin to a staircase, for the electrons to travel along to assist the tunneling electrons through the tunnel junction 104. The additional quantum states provided by the nanoparticles 116 reduce the resistance across tunnel junction 104, and, thus, reduces the voltage drop across the tunnel junction 104. This reduction in voltage drop increases the efficiency of the cascaded solar cell 100.

Further, the nanoparticles can make a tunnel junction 104 that would be unacceptable in terms of performance of the cascaded solar cell 100 reach acceptable levels of current generation for the cascaded solar cell 100.

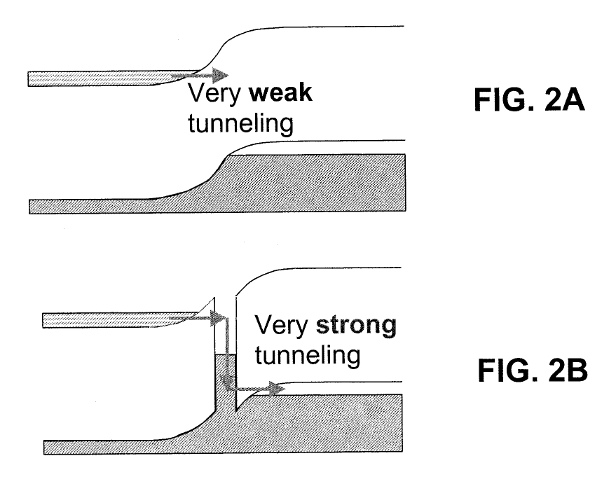

FIGS. 2A and 2B illustrate Fermi-levels for the related art and for a solar cell in accordance with the present invention.

By incorporating metallic (or semi-metallic) nanoparticles 116 into the n⁺p⁺ tunnel junction 104, the present invention creates a large number of midgap states, effectively halving the tunneling distance for electrons. FIG. 2A illustrates the weak tunneling approach used by the related art, and FIG. 2B illustrates the strong tunneling approach of the present invention. Because tunneling current density decreases exponentially with tunneling distance, the result is a drastic increase in tunnel current for a particular voltage. Because the elements of a cascaded photovoltaic cell 100 are connected in series, all of the current in the circuit must pass through the tunnel junction 104. With an improved tunnel junction 104, a substantially smaller voltage is lost in the tunnel junction 104 while passing the generated current.

Experimental Data

The implementation of this principle tested experimentally comprises nanoparticle 116 islands (1.2 monolayers of deposition) of ErAs (a semimetal) grown epitaxially within a GaAs tunnel junction 104 grown by Molecular Beam Epitaxy. The p⁺ layer 112 of the tunnel junction 104 is doped with beryllium at a concentration of 1×10²⁰ cm⁻³ while the n⁺ layer 114 is doped with silicon at a concentration of 5×10¹⁸ cm⁻³. Testing an Al_{0.3}Ga_{0.7}As/GaAs cascaded photovoltaic using this tunnel junction, the voltage (and therefore the efficiency) of the tandem cell with ErAs at the interface was approximately double the tandem cell without ErAs.

As described above, a different metal (or semimetal) can be used at the nanoparticle 116 interface, and the tunnel junction 104 can be made out of a different material or by a different technique. Different dopants or concentrations can be used. The growth does not necessarily have to be epitaxial.

The present invention illustrates that the incorporation of metal or semi-metal nanoparticles 116 at the tunnel junction 104 interface results in a much better tunnel junction 104. As a result, substantially less voltage is lost in the tunnel junction 104, increasing the overall voltage of the device, to nearly the ideal sum of the voltages generated in the individual elements. The physics of enhanced tunnel junctions using metal particles are fairly robust and may potentially allow improved tunnel junctions in a wide range of cascaded photovoltaic solar cells 100. Because the technique of the present invention will make a “bad” tunnel junction 104 better, the present invention offers the potential to create an efficient tunnel junction 104 with relatively little effort in systems where efficient tunnel junctions 104 are otherwise not possible. For example, and not by way of limitation, efficient tunnel junctions can be grown on a flexible substrate, rather than a semiconductor substrate, by using the present invention.

Further, although described with respect to a solar cell, the improved tunnel junction can be used in any device that uses a tunnel junction without departing from the scope of the present invention. So, for example, and not by way of limitation, in a Multiple Active Region (MAR) laser/light emitting diode, current is generally passed through tunnel junction(s) under reverse bias (as opposed to forward bias in solar cells) in order to generate electron-hole pairs in each active region. If the tunnel junction(s) in the laser are lossy, then the overall efficiency of the laser/emitter is reduced. MAR LEDs and lasers, the key point is that the active regions are interconnected with tunnel junctions. Using lower resistance (i.e. enhanced) tunnel junctions will reduce parasitic losses in the devices.

Flowchart

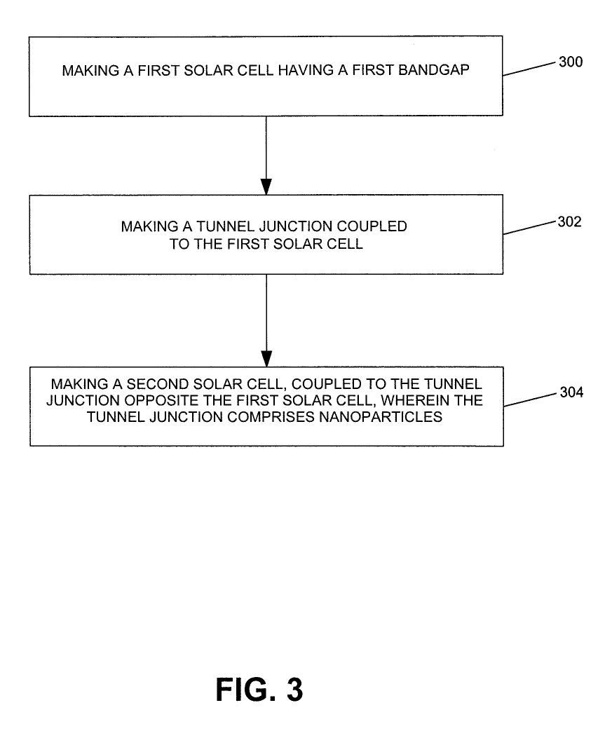

FIG. 3 is a flowchart illustrating a method for employing the present invention.

Box 300 illustrates making a first solar cell having a first bandgap.

Box 302 illustrates making a tunnel junction coupled to the first solar cell.

Box 304 illustrates making a second solar cell, coupled to the tunnel junction opposite the first solar cell, wherein the tunnel junction comprises nanoparticles.

### REFERENCES

The following references are incorporated by reference herein:
[1]: V. Noveski, R. Schlesser, B. Raghothamachar, M. Dudley, S. Mahajan, S. Beaudoin, Z. Sitar, J. Crystal Growth 279 (2005) 13-19.
[2]: G. A. Slack, T. F. McNelly, J. Crystal Growth 34 (1976) 263-279.
[3]: M. Bickermann, B. M. Epelbaum, A. Winnacker, Phys. Stat. Sol. (c) 0, No. 7, 1993-1996 (2003).
[4]: G. A. Slack, T. F. McNelly, J. Crystal Growth 42 (1977) 560-563.
[5]: P. Pohl, F. H. Renner, M. Echkardt, A. Schwanhaeusser, A. Friedrich, O. Yueksekdag, S. Malzer, G. H. Doehler, P. Kiesel, D. Driscoll, M. Hanson, A. C. Gossard. Appl. Phys. Lett. 83, 4035 (2003).
[6]: Increased efficiency in multijunction solar cells through the incorporation of semimetallic ErAs nanoparticles into the tunnel junction. J. M. O. Zide, A. Kleiman-Shwarsctein, N. C. Strandwitz, J. D. Zimmerman, T. Steenblock-Smith, A. C. Gossard, A. Forman, A. Ivanovskaya, and G. D. Stucky, attached herewith (2005).

### CONCLUSION

This concludes the description of the preferred embodiment of the present invention. The present invention discloses a method that incorporates metallic nanoparticles at the p⁺-n⁺ tunnel junction in a cascaded photovoltaic solar cell. The use of the nanoparticles enhances the tunneling current density through the tunnel junction. As such, the efficiency of the solar cell is increased.

A method in accordance with the present invention comprises making a first solar cell having a first bandgap, making a tunnel junction coupled to the first solar cell, and making a second solar cell having a second bandgap, coupled to the tunnel junction opposite the first solar cell, wherein the tunnel junction comprises nanoparticles.

Such a method further optionally includes the nanoparticles being a metal, a semi metal, or a narrow bandgap semiconductor material, specifically a semi-metal of erbium arsenide, the nanoparticles being deposited in an island structure within the tunnel junction, and the first solar cell being deposited on a flexible substrate.

A device in accordance with the present invention comprises a tunnel junction, wherein the tunnel junction comprises nanoparticles between the n+ layer and the p+ layer of the tunnel junction.

Such a device further optionally includes the device being a cascaded solar cell, the nanoparticles are a metal or semi-metal, specifically a semi-metal of erbium arsenide, or a narrow bandgap semiconductor material, the device being fabricated on a flexible substrate, the device having a plurality of active regions interconnected with a plurality of tunnel junctions, and current is passed through the plurality of tunnel junctions under reverse bias in order to generate electron-hole pairs in each active region in the plurality of active regions, and at least one tunnel junction of the plurality of tunnel junctions is an enhanced tunnel junction with reduced resistance.

A cascaded solar cell in accordance with the present invention comprises a first cell having a first bandgap, a tunnel junction, coupled to the first cell, the tunnel junction further comprising a plurality of nanoparticles, and a second cell having a second bandgap, the second cell being coupled to the tunnel junction, wherein the second bandgap is wider than the first bandgap.

Such a cascaded solar cell further optionally includes the plurality of nanoparticles being located between an n+ layer and a p+ layer of the tunnel junction, the nanoparticles being a metal or a semi-metal, the nanoparticles being erbium arsenide, and the nanoparticles being a narrow bandgap semiconductor material.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for making a cascaded solar cell, comprising:
making a first solar cell having a first bandgap;
making a tunnel junction coupled to the first solar cell; and
making a second solar cell having a second bandgap, coupled to the tunnel junction opposite the first solar cell, wherein the tunnel junction comprises nanoparticles.

2. The method of claim 1, wherein the nanoparticles are a metal.

3. The method of claim 1, wherein the nanoparticles are a semi-metal.

4. The method of claim 3, wherein the nanoparticles are erbium arsenide.

5. The method of claim 1, wherein the nanoparticles are deposited in an island structure within the tunnel junction.

6. The method of claim 1, wherein the first solar cell is deposited on a flexible substrate.

7. The method of claim 1, wherein the nanoparticles are a narrow bandgap semiconductor material.

8. A device comprising a tunnel junction, wherein the tunnel junction comprises nanoparticles between an n+ layer and a p+ layer of the tunnel junction.

9. The device of claim 8, wherein the device is a cascaded solar cell.

10. The device of claim 10, wherein the nanoparticles are erbium arsenide.

11. The device of claim 8, wherein the nanoparticles are a narrow bandgap semiconductor material.

12. The device of claim 8, wherein the device is fabricated on a flexible substrate.

13. The device of claim 8, wherein the device has a plurality of active regions interconnected with a plurality of tunnel junctions, and current is passed through the plurality of tunnel junctions under reverse bias in order to generate electron-hole pairs in each active region in the plurality of active regions.

14. The device of claim 13, wherein at least one tunnel junction of the plurality of tunnel junctions is an enhanced tunnel junction with reduced resistance.

15. A cascaded solar cell, comprising:
a first cell having a first bandgap;
a tunnel junction, coupled to the first cell, the tunnel junction further comprising a plurality of nanoparticles; and
a second cell having a second bandgap, the second cell being coupled to the tunnel junction, wherein the second bandgap is wider than the first bandgap.

16. The cascaded solar cell of claim 15, wherein the plurality of nanoparticles are located between an n+ layer and a p+ layer of the tunnel junction.

17. The cascaded solar cell of claim 16, wherein the nanoparticles are a metal.

18. The cascaded solar cell of claim 16, wherein the nanoparticles are a semi-metal.

19. The cascaded solar cell of claim 16, wherein the nanoparticles are erbium arsenide.

20. The cascaded solar cell of claim 16, wherein the nanoparticles are a narrow bandgap semiconductor material.
